(19) United States
(12) Patent Application Publication
(10) Pub. No.: US 2022/0037479 A1
(43) Pub. Date: Feb. 3, 2022

(54) OXIDE LAYER, SEMICONDUCTOR STRUCTURE, AND MANUFACTURING METHODS THEREFOR

(71) Applicant: CHANGXIN MEMORY TECHNOLOGIES, INC., Hefei City (CN)

(72) Inventor: Li ZHANG, Hefei (CN)

(73) Assignee: CHANGXIN MEMORY TECHNOLOGIES, INC., Hefei City (CN)

(21) Appl. No.: 17/447,183

(22) Filed: Sep. 8, 2021

Related U.S. Application Data
(63) Continuation of application No. PCT/CN2021/103604, filed on Jun. 30, 2021.

(30) Foreign Application Priority Data
Aug. 3, 2020 (CN) 202010765569.2

(51) Int. Cl. H01L 29/40; H01L 29/423; H01L 29/51; H01L 21/28

(52) U.S. Cl. CPC H01L 29/401; H01L 29/42364; H01L 27/10873; H01L 29/518; H01L 21/28202; H01L 29/511

(57) ABSTRACT

A method for manufacturing an oxide layer includes: reacting a nitrogen-oxide-containing gas with hydrogen at a first temperature to form a first oxide layer, a volume concentration of the hydrogen in a first reaction gas being a first concentration; and reacting oxygen with hydrogen at a second temperature to form a second oxide layer on a surface of the first oxide layer, a volume concentration of the hydrogen in a second reaction gas being a second concentration; where the first temperature is less than the second temperature, and the first concentration is greater than the second concentration.

### CROSS-REFERENCE TO RELATED APPLICATIONS

This is a continuation of International Patent Application No. PCT/CN2021/103604 filed on Jun. 30, 2021, which claims priority to Chinese Patent Application No. 202010765569.2 filed on Aug. 3, 2020. The disclosures of these applications are hereby incorporated by reference in their entirety.

### BACKGROUND

With the development of a semiconductor technology, to satisfy the requirements of device miniaturization, the size of a Dynamic Random-Access Memory (DRAM) is getting smaller and smaller, and consequently the requirements for the uniformity and compactness of an oxide layer are continuously improved.

### SUMMARY

The present disclosure relates generally to the field of integrated circuit technologies, and more specifically to an oxide layer, a semiconductor structure, and manufacturing methods therefor.

According to various embodiments, provided are a method for manufacturing an oxide layer, a semiconductor structure and a manufacturing method therefor.

A method for manufacturing an oxide layer includes:

reacting a nitrogen-oxide-containing gas with hydrogen at a first temperature to form a first oxide layer, a volume concentration of the hydrogen in a reaction gas being a first concentration; and

reacting oxygen with hydrogen at a second temperature to form a second oxide layer on a surface of the first oxide layer, a volume concentration of the hydrogen in a reaction gas being a second concentration;

where the first temperature is less than the second temperature, and the first concentration is greater than the second concentration.

Provided is an oxide layer, and the oxide layer is manufactured by using the manufacturing method.

A method for manufacturing a semiconductor structure includes:

providing a substrate;

forming an inter-gate dielectric layer on a surface of the substrate, where the inter-gate dielectric layer includes an oxide layer, and the oxide layer is formed by using the method for manufacturing an oxide layer;

forming a gate conductive layer on the surface of the inter-gate dielectric layer distal from the substrate;

patterning the inter-gate dielectric layer and the gate conductive layer to form a gate structure; and

forming a side wall on a sidewall of the gate structure.

Provided is a semiconductor structure, and the semiconductor structure is manufactured by using the manufacturing method.

### BRIEF DESCRIPTION OF THE DRAWINGS

To describe the technical solutions in embodiments of the present disclosure or the conventional art more clearly, the accompanying drawings required for describing the embodiments or the conventional art are briefly introduced below. Apparently, the accompanying drawings in the following description show merely some embodiments of the present disclosure, and a person of ordinary skill in the art can still derive other accompanying drawings from these accompanying drawings without creative efforts.

FIG. 1 is a flowchart of a method for manufacturing an oxide layer provided by one embodiment.

FIG. 2 is a schematic cross-sectional diagram of the manufacturing process for an oxide layer provided by another embodiment.

FIG. 3 is a schematic diagram of temperature changes in a first oxidation stage and a second oxidation stage of the manufacturing process for an oxide layer provided by one embodiment.

FIG. 4 is a schematic diagram of forming first oxide layers by a plurality of devices on a surface of a substrate provided by one embodiment.

FIG. 5 is a schematic cross-sectional diagram of a manufacturing process for a semiconductor structure provided by one embodiment.

### DETAILED DESCRIPTION

To facilitate the understanding of the present disclosure, the following will make a more comprehensive description of the present disclosure with reference to the related accompanying drawings. The embodiments of the present disclosure are shown in the accompanying drawings. However, the present disclosure can be implemented in many different forms, and is not limited to the embodiments described herein. On the contrary, the purpose of providing these embodiments is to make the disclosure of the present disclosure more thorough and comprehensive.

Unless otherwise defined, all technical and scientific terms used herein have the same meaning as commonly understood by a person skilled in the technical field of the present disclosure. The terms used in the description of the present disclosure herein is only for the purpose of describing specific embodiments, and is not intended to limit the present disclosure.

It should be understood that when an element or layer is referred to as being “on . . . ”, “adjacent to . . . ”, “connected to”, or “coupled to” other elements or layers, it can be directly on the other elements or layers, adjacent to, connected, or coupled to the other elements or layers, or there may be an intervening element or layer. In contrast, when an element is referred to as being “directly on . . . ”, “directly adjacent to . . . ”, “directly connected to”, or “directly coupled to” other elements or layers, there is no intervening element or layer. It should be understood that although the terms, first, second, third, etc., may be used to describe various elements, components, regions, layers, doping types and/or parts, these elements, components, regions, layers, doping types and/or parts should not be limited by these terms. These terms are only used to distinguish one element, component, region, layer, doping type or part from another element, component, region, layer, doping type or part. Therefore, without departing from the teaching of the present disclosure, the first element, component, region, layer, doping type or part discussed below can be expressed as a second element, component, region, layer or part. For example, a first doping type may become a second doping type, and similarly, the second doping type may become the first doping type. The first doping type and the second doping type are different doping types, for example, the first doping type may be P-type and the second doping type may be N-type, or the first doping type may be N-type and the second doping type may be P-type.

Spatial relationship terms, such as “under . . . ”, “beneath . . . ”, “lower, “below . . . ”, “above . . . ”, and “upper”, can be used herein to describe the relationships between one element or feature shown in the drawings and other elements or features. It should be understood that in addition to the orientations shown in the drawings, the spatial relationship terms also include different orientations of devices in use and operation. For example, if the device in the drawings is turned over, the element or feature described as “beneath” or “below” or “under” other elements will be oriented “on” the other elements or features. Therefore, the exemplary terms “beneath” and “under” can include both two orientations, i.e., up and down. In addition, the device may also include other orientations (for example, a 90-degree rotation or other orientations), and the spatial descriptors used herein are explained accordingly.

When used herein, the singular forms, “a”, “one” and “the/this”, may also include plural forms, unless the context clearly dictates otherwise. It should also be understood that the terms “comprising/including” or “having”, etc. specify the existence of the stated feature, whole, step, operation, component, part, or a combination, but the possibility of the existence or addition of one or more other features, wholes, steps, operations, components, parts, or combinations thereof is not excluded. Meanwhile, in this description, the term “and/or” includes any and all combinations of related listed items.

The embodiments of the present disclosure are described herein with reference to cross-sectional views as schematic diagrams of ideal embodiments (and intermediate structures) of the present disclosure, so that changes in the shown shape due to, for example, a manufacturing technology and/or tolerance can be expected. Therefore, the embodiments of the present disclosure should not be limited to the specific shape of the region shown herein, but include a shape deviation due to, for example, the manufacturing technology. For example, an implantation region shown as a rectangle usually has a round or curved feature and/or implantation concentration gradient at an edge thereof, rather than a binary change from the implantation region to a non-implantation region. Likewise, a buried region formed by implantation may result in some implantations in the region between the buried region and the surface through which the implantation passes. Therefore, the regions shown in the drawings are essentially schematic, and the shapes thereof do not represent the actual shapes of the regions of the device, and do not limit the scope of the present disclosure.

In a process, an oxide layer is generally prepared by the reaction of H₂ and O₂. Taking a gate oxide layer as the oxide layer as an example, specifically, a gate oxide layer dielectric can be grown by means of In-Situ Steam Generation (ISSG). The principle is to introduce an initial reaction gas (H₂+O₂) into a reaction chamber where a wafer is placed, and H₂ and O₂ react directly on the surface of the wafer through a radiant rapid heating technology. However, in the foregoing method, the reaction rate of H₂+O₂ is too high, which is unfavorable for the control of a manufacturing process. Therefore, the industry is now considering reducing the reaction rate by reacting an oxynitride such as N₂O with H₂. However, N₂O is easy to form SiON on an oxide interface under a high temperature condition, which will reduce interface carrier mobility, thereby reducing the performance of a device.

The inventor of the present disclosure has recognized through research that to satisfy the small size requirement of a Dynamic Random-Access Memory (DRAM), a thickness of an oxide layer, especially a gate oxide layer, will be reduced as much as possible. Moreover, as the thickness of the oxide layer continues to decrease, the time of the manufacturing process thereof also continues to shorten. However, the reaction rate of hydrogen and oxygen is relatively high, which is more unfavorable for controlling the manufacturing process. Therefore, to reduce the reaction rate, the reaction of a nitrogen-oxide-containing gas and hydrogen is used to reduce the reaction rate and generate the oxide layer. However, at a relatively high temperature, the nitrogen-oxide-containing gas is easy to generate silicon oxynitride on an interface where an oxide is generated. Therefore, if the foregoing method is used to manufacture a gate oxide layer, the silicon oxynitride generated on the oxide interface will reduce interface carrier mobility, thereby reducing the performance of the device.

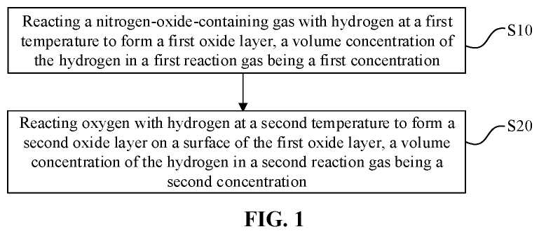

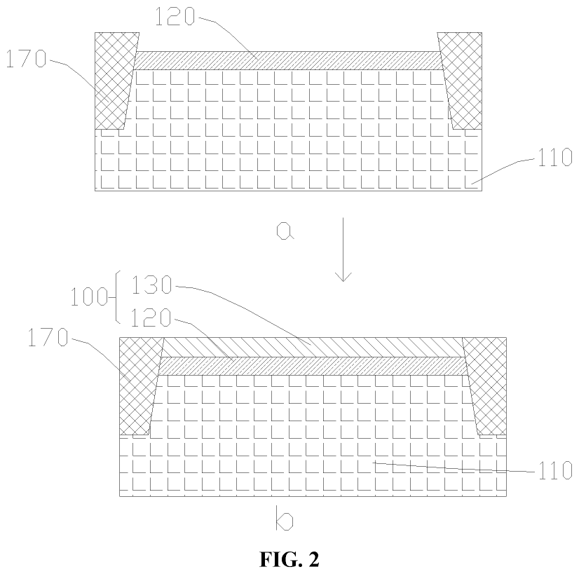

Referring to FIG. 1 and FIG. 2, according to an embodiment, provided is a method for manufacturing an oxide layer 100, including the following steps.

At S10, a nitrogen-oxide-containing gas is reacted with hydrogen at a first temperature to form a first oxide layer, a volume concentration of the hydrogen in a reaction gas being a first concentration.

At S20, oxygen is reacted with hydrogen at a second temperature to form a second oxide layer on a surface of the first oxide layer, a volume concentration of the hydrogen in a reaction gas being a second concentration.

The first temperature is less than the second temperature, and the first concentration is greater than the second concentration.

In S10, referring to panel “a” of FIG. 2, the first oxide layer 120 can be formed on a surface of a substrate 110.

The first oxide layer 120 formed on the surface of the substrate 110 by the reaction of the nitrogen-oxide-containing gas and the hydrogen can be a silicon oxide layer. The first oxide layer 120 formed by the reaction of the nitrogen-oxide-containing gas and the hydrogen can be doped with a nitrogen element to form Si—O—N defects. The purity of the first oxide layer 120 will decrease. The decrease in the purity of the first oxide layer 120 can cause the oxide layer 100 to be broken down. As a result, a device having the oxide layer 100 fails. Moreover, during the reaction of the oxygen and the hydrogen, when the concentration of the hydrogen is relatively high, the formation of oxygen free radicals will be accelerated, and the combination of the oxygen free radicals and silicon atoms can reduce the defects of the first oxide layer 120. However, if the concentration of the hydrogen is too high, hydrogen free radicals and hydroxyl free radicals will participate in the reaction. In the process of forming the first oxide layer 120, H—Si—O is formed. However, the chemical bond of Si—H is unstable, which will cause Si—H to break at a high temperature to form a dangling bond of Si. Moreover, the reaction of the nitrogen-oxide-containing gas and the hydrogen can avoid or reduce the occurrence of Si—H defects in the first oxide layer 120. Meanwhile, the rate at which the nitrogen-oxide-containing gas reacts with the hydrogen to generate the oxygen free radicals is relatively low. To reduce the defects of the first oxide layer 120, the concentration of the hydrogen can be increased to generate more oxygen free radicals.

Therefore, after the nitrogen-oxide-containing gas is substituted for the oxygen, the use of the hydrogen with a relatively high concentration can accelerate the generation of the oxygen free radicals by the nitrogen-oxide-containing gas. Therefore, the defects of the first oxide layer 120 can be reduced or avoided, and at the same time, the Si—H defects can be avoided.

Moreover, the rate at which the nitrogen-oxide-containing gas can react with the hydrogen is lower than the rate at which the hydrogen reacts with the oxygen, and therefore, the reaction rate can be reduced, facilitating the control of the manufacturing process of the oxide layer. Further, a first oxidation stage is performed at a relatively low temperature, which can further reduce the reaction rate, facilitating the control of the manufacturing process of the first oxide layer 120, so as to improve the uniformity of the first oxide layer 120.

In one embodiment, the material of the substrate 110 is silicon or silicon nitride or others.

In S20, referring to panel “b” of FIG. 2, the hydrogen with a relatively low first concentration is used to react with the oxygen, which can avoid the occurrence of the Si—H defects on the interface between the first oxide layer 120 and the second oxide layer 130. Further, the second oxide layer 130 is generated by the reaction of the hydrogen and the oxygen, which can avoid the occurrence of the Si—N defects on the interface between silicon and silicon oxide by using the nitrogen-oxide-containing gas. Therefore, the uniformity of the second oxide layer 130 can be improved. Furthermore, the hydrogen with a relatively low concentration is used to react with the oxygen, which can also reduce the reaction rate, facilitating the control of the manufacturing process of the second oxide layer 130.

According to the method for manufacturing an oxide layer 100 provided by the embodiments of the present disclosure, the manufacturing process of the oxide layer 100 is divided into a first oxidation stage and a second oxidation stage. During the first oxidation stage, the reaction temperature is the first temperature. The first oxide layer 120 is formed by the reaction of the nitrogen-oxide-containing gas and the hydrogen, and the concentration of the hydrogen in the reaction gas is the first concentration. During the second oxidation stage, the reaction temperature is the second temperature. The second oxide layer 130 is formed on the surface of the first oxide layer 120 by the reaction of the oxygen and the hydrogen, and the concentration of the hydrogen in the reaction gas is the second concentration. The first temperature is less than the second temperature, and the first concentration is greater than the second concentration. Through the first oxidation stage and the second oxidation stage, the first oxide layer 120 and the second oxide layer 130 are respectively obtained. The first oxide layer 120 and the second oxide layer 130 constitute the oxide layer 100.

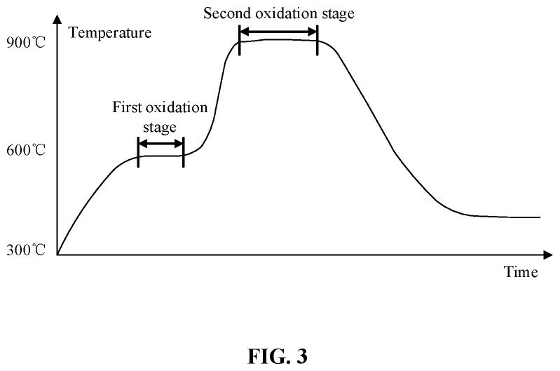

Referring to FIG. 3, in the first oxidation stage, the first temperature is relatively low, and therefore, the reaction rate of the nitrogen-oxide-containing gas and the hydrogen can be reduced. When the reaction rate is relatively low, there can be relatively sufficient time to control the manufacturing process of the first oxide layer 120, and the first oxide layer 120 with relatively high uniformity can be obtained. The use of hydrogen with a relatively high concentration can accelerate the generation of oxygen free radicals by the nitrogen-oxide-containing gas to reduce the defects of the first oxide layer 120. In the second oxidation stage, the hydrogen reacts with the oxygen, and the first temperature is relatively high and the second concentration is relatively low. Therefore, the occurrence of the Si—N defects and the Si—H defects in the oxide layer 100 can be avoided while the reaction rate of the oxygen and the hydrogen is reduced. The method for manufacturing an oxide layer 100 can effectively improve the reliability of the oxide layer 100 and ensure the performance of the oxide layer 100.

In one embodiment, both the first oxide layer 120 and the second oxide layer 130 are manufactured by using an In-Situ Steam Generation (ISSG) process. That is to say, the ISSG process is used in both the first oxidation stage and the second oxidation stage. The ISSG process is a new low-pressure rapid thermal oxidation annealing process technology, which is, in a low-pressure rapid thermal oxidation chamber, to usually use high-purity oxygen and hydrogen to form diluted steam on the surface of the substrate 110. When the hydrogen and the oxygen are rapidly oxidized at a high temperature, a chemical reaction similar to combustion occurs on the surface of the substrate 110. In this reaction, many gas-phase active free radicals will be generated in the chamber. Most of these free radicals are the oxygen free radicals that easily react with silicon atoms, and the oxygen free radicals have a strong oxidation function and can form a thin film with good uniformity with the silicon atoms. The formed thin film has relatively few internal defects, and the silicon-oxygen interface is relatively smooth. Therefore, the high-quality oxide layer 100 can be manufactured.

It can be understood that, in the embodiments of the present disclosure, the ISSG process is divided into two stages. In the first oxidation stage, the nitrogen-oxide-containing gas reacts with the hydrogen, and in the second oxidation stage, the oxygen reacts with the hydrogen. Moreover, the first temperature in the first oxidation stage is less than the second temperature in the second oxidation stage. The first concentration of the hydrogen in the first oxidation stage is greater than the second concentration of the hydrogen in the second oxidation stage, which can further improve the reliability of the oxide layer 100.

In one embodiment, the first temperature is 600° C. to 800° C. Specifically, the first temperature can be 600° C., 650° C., 700° C., 750° C., or 800° C., etc. That is, the lower limit value of the first temperature can not be less than 600° C., and the upper limit value of the first temperature can not be greater than 800° C. In this temperature range, the reaction rate of the nitrogen-oxide-containing gas and the hydrogen is relatively low, and relatively ample time can be left to adjust the manufacturing process of the first oxide layer 120 in a timely manner. Therefore, it is convenient to perform targeted operation on the first oxide layer 120 to improve the uniformity of the first oxide layer 120. Further, the lower limit value of the first temperature can not be less than 650° C. The upper limit value of the first temperature can not be greater than 750° C. In one embodiment, the lower limit value of the first temperature can not be greater than 700° C., and the upper limit value of the first temperature can not be greater than 730° C. In one embodiment, the first temperature can be 720° C. or 725° C. The first temperature uses the temperature value, and there can be a relatively high reaction rate without affecting the adjustment of the manufacturing process.

In one embodiment, the second temperature is 800° C. to 1050° C. Specifically, the second temperature can be 800° C., 850° C., 900° C., 950° C., 1000° C., or 1050° C., etc. That is, the lower limit value of the second temperature is not less than 800° C., and the upper limit value of the second temperature is not greater than 1050° C. That is, the minimum value of the second temperature is greater than or equal to 800° C. The upper limit value of the second temperature is less than or equal to 1050° C. In the second reaction stage, the second concentration of the hydrogen is relatively low. In this temperature range, it can be ensured that the hydrogen and the oxygen have a relatively high reaction rate, and certain production efficiency can be ensured without affecting the control of the manufacturing process.

In one embodiment, the lower limit value of the second temperature is greater than 900° C., and the upper limit value of the second temperature is not greater than 1000° C. In one embodiment, the lower limit value of the second temperature is greater than 950° C., and the upper limit value of the second temperature is not greater than 980° C. In one embodiment, the second temperature can be 970° C. or 975° C.

In one embodiment, the first concentration is 5% to 33%. Specifically, the first concentration can be 5%, 10%, 15%, 20%, 25%, 30%, or 33%. That is, the lower limit value of the first concentration can not be less than 5%, and the upper limit value of the first concentration can not be greater than 33%. That is, the lower limit value of the first concentration is greater than or equal to 5%. The upper limit value of the first concentration is less than or equal to 33%. In this concentration range, the hydrogen can accelerate the generation of oxygen free radicals by the nitrogen-oxide-containing gas to reduce the defects of the first oxide layer 120. In one embodiment, the lower limit value of the first concentration is not less than 10%, and the upper limit value of the first concentration is not greater than 25%. In one embodiment, the lower limit value of the first concentration is not less than 20%, and the upper limit value of the first concentration is not greater than 23%. In one embodiment, the first concentration can be 21% or 23%, and at this concentration, the defects of the first oxide layer 120 can be eliminated best.

The second concentration can be less than 5%. Specifically, the second concentration can be 0.5%, 1%, 1.5%, 2.5%, 3%, 3.5%, 4.5%, or 4.5%. In this concentration range, the occurrence of the Si—H defects in the oxide layer 100 can be reduced. In one embodiment, the lower limit value of the second concentration is not less than 1%, and the upper limit value of the second concentration is not greater than 3%. In one embodiment, the second concentration can be 1.5% or 2%. At this concentration value, fewest Si—H defects occur in the oxide layer 100, and a certain reaction rate can be ensured, thereby improving production efficiency.

In one embodiment, in the first oxidation stage, the first temperature used can be 720° C. The concentration of the hydrogen can be 21%, that is to say, the concentration of the nitrogen-oxide-containing gas is 79%. In the second oxidation stage, the second temperature used can be 970° C., and the concentration of the hydrogen can be 1.5%, that is to say, the concentration of the oxygen can be 98.5%.

In another embodiment, in the first oxidation stage, the first temperature used can be 725° C. The concentration of the hydrogen can be 23%, that is to say, the concentration of the oxygen is 77%. In the second oxidation stage, the second temperature used can be 975° C., and the concentration of the hydrogen can be 2%, that is to say, the concentration of the oxygen can be 98%.

In the foregoing embodiments, in the first stage and the second stage, different temperature combinations and concentration combinations of the hydrogen can reduce the formation rate of the oxide layer 100 and facilitate precise control of the entire manufacturing process, so as to improve the uniformity and reliability of the oxide layer 100.

In one embodiment, the nitrogen-oxide-containing gas includes one or more of nitrous oxide (N₂O), nitric oxide (NO), nitrogen dioxide (NO₂), dinitrogen trioxide (N₂O₃), dinitrogen tetroxide (N₂O₄), or dinitrogen pentoxide (N₂O₅). The reaction rate of the nitrogen-oxide-containing gas and the hydrogen is relatively low, so that the manufacturing process can be easily controlled.

In one embodiment, a thickness of the first oxide layer 120 accounts for 20%-50% of a thickness of the oxide layer 100. That is, a thickness of the second oxide layer 130 accounts for 50% to 80% of the thickness of the oxide layer. The oxide layer 100 manufactured in this proportion range can have good uniformity and compactness.

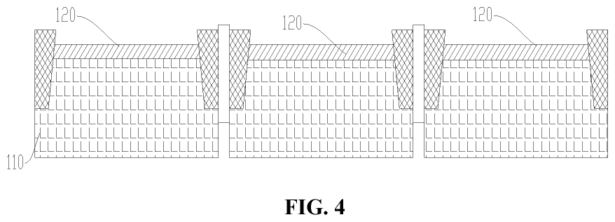

Referring to FIG. 4, it can be understood that a plurality of devices can be formed on the substrate 110. The devices can be isolated from each other. Each of the devices can form the first oxide layer 120. Then, the second oxide layer 130 can be formed on the surface of the first oxide layer 120. Through the method for manufacturing an oxide layer 100 provided by the foregoing embodiments, the oxide layers 100 on the plurality of devices can be formed in the same manufacturing process, which can improve production efficiency. Further, regardless of the devices on an edge of the substrate 110 or in a middle of the substrate 110, the thickness of the first oxide layer 120 of each device is highly consistent with the flatness and uniformity of the surface, and therefore, the yield of the device can be significantly improved.

The embodiments of the present disclosure further provide an oxide layer 10.

The oxide layer 10 is manufactured by using the manufacturing method in the foregoing embodiments. The method provided by the foregoing embodiments is not limited to being applicable to the oxide layer 100, and the structure of any oxide layer that can be obtained by using this method can be applicable to the method provided by the embodiments of the present disclosure.

It can be understood that the oxide layer 100 can be, but is not limited to, a gate oxide layer in a gate structure. By manufacturing the gate oxide layer by the method provided by the foregoing embodiments, the formation of Si—H between the gate oxide layer and the substrate 110 can be avoided, and therefore, interface carrier mobility can be improved.

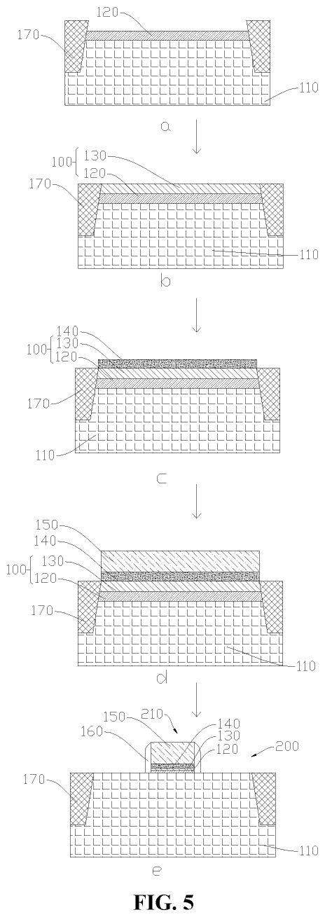

Referring to FIG. 5, the embodiments of the present disclosure further provide a manufacturing method for a semiconductor structure 200. The manufacturing method for a semiconductor structure includes the following steps.

At S110, referring to panel “a” and panel “b” of FIG. 5, a substrate 110 is provided.

At S120, an inter-gate dielectric layer 140 is formed on a surface of the substrate 110, where the inter-gate dielectric layer 140 includes an oxide layer 100, and the oxide layer 100 is formed by using the method for manufacturing an oxide layer in the foregoing embodiments.

At S130, a gate conductive layer 150 is formed on the surface of the inter-gate dielectric layer 140 distal from the substrate 110.

S140, patterning is performed on the inter-gate dielectric layer 140 and the gate conductive layer 150 to form a gate structure 210.

S150, a side wall 160 is formed on a sidewall of the gate structure 210.

Referring to FIG. 5, panel “c”, in S120, after a first oxide layer 120 and a second oxide layer 130 are formed on the surface of the substrate 110, the oxide layer 100 formed by the first oxide layer 120 and the second oxide layer 130 together can be used as the inter-gate dielectric layer, that is, at this time, the inter-gate dielectric layer can only include the oxide layer 100. The inter-gate dielectric layer 140 can have an insulation function. In one embodiment, the gate conductive layer 150 is formed on the surface of the inter-gate dielectric layer 140 distal from the substrate 110.

Referring to FIG. 5, panel “d”, in S130, the gate conductive layer 150 is formed on the side of the second oxide layer 130 distal from the substrate. The gate conductive layer 150 can be formed on the surface of the inter-gate dielectric layer 140 distal from the oxide layer 100. It can be understood that a structure formed by the oxide layer 100 and the gate conductive layer 150 can be applied to a Metal-Oxide Semiconductor Field Effect Transistor (MOSFET). In one embodiment, the gate conductive layer 150 can be a doped polysilicon layer. Certainly, in other embodiments, the gate conductive layer 150 can also be a metal layer.

Referring to FIG. 5, panel “e”, in S140, patterning process can be performed on the first oxide layer 120, the second oxide layer 130, the inter-gate dielectric layer 140, and the gate conductive layer 150 to form the gate structure 210. The gate structure 210 can be applied to an MOSFET. In S150, the side wall 160 is formed on a side surface of the gate structure 210 through material deposition patterning process, so as to achieve the purpose of protecting the gate structure 210. The side wall 160 can be an oxide layer, a nitride layer, or a stack structure including an oxide layer and a nitride layer, such as an ONO (oxide layer-nitride layer-oxide layer) structure.

In one embodiment, the forming an inter-gate dielectric layer 140 on a surface of the substrate 110 further includes the following step.

A nitride layer is formed on the surface of the oxide layer 100 distal from the substrate 110. The nitride layer and the oxide layer 100 together constitute the inter-gate dielectric layer 140. The nitride layer can have the function of preventing the inter-gate dielectric layer 140 from being broken down, and can improve the reliability of the semiconductor structure 200. In one embodiment, the nitride layer includes at least one of a plasma nitriding layer and a silicon oxynitride layer. The plasma nitriding layer can be manufactured by using a Remote Plasma Nitriding (RPN) process.

In one embodiment, a shallow trench isolation structure 170 is formed in the substrate 110. The shallow trench isolation structure 170 isolates several active regions in the substrate 110. The inter-gate dielectric layer 140 is formed on surfaces of the active regions. The shallow trench isolation structure 170 can be manufactured by using a process below 0.25 um. In one embodiment, a mask layer can be formed on the surface of the substrate 110, and then the substrate 100 can be etched based on the mask layer to form the shallow trench isolation structure 170 in the substrate 100. The shallow trench isolation structure 170 can be filled with an isolation material layer. In one embodiment, the isolation material layer can be deposited integrally on inner walls of the substrate 110 and the shallow trench isolation structure 170, then the isolation material layer located on the surface of the substrate 110 can be removed by a planarization process or a grinding process, and the isolation material layer remaining in the shallow trench isolation structure 170 is retained. The isolation material layer can have an isolation function to form the active regions.

The embodiments of the present disclosure further provide a semiconductor structure 200. The semiconductor structure 200 is obtained by using the manufacturing method for a semiconductor structure 200.

It should be understood that although the various steps in the flowchart of FIG. 1 are displayed in sequence as indicated by arrows, these steps are not necessarily executed in sequence in the order indicated by the arrows. Unless specifically stated herein, the execution of these steps is not strictly limited in order, and these steps can be executed in other orders. Moreover, at least part of the steps in FIG. 1 can include a plurality of steps or a plurality of stages. These steps or stages are not necessarily executed at the same moment, but can be executed at different moments. The order of execution of these steps or stages is not necessarily performing in sequence, but can be execution in turn or alternately with other steps or at least part of steps or stages in the other steps.

In the present disclosure, descriptions with reference to the terms “some embodiments”, “other embodiments”, “ideal embodiments”, etc. mean that specific features, structures, materials, or characteristics described in combination with the embodiments or examples are included in at least one embodiment or example of this specification. In this description, the schematic descriptions of the terms do not necessarily refer to the same embodiments or examples.

The technical features in the foregoing embodiments can be combined arbitrarily. To make the descriptions concise, all possible combinations of the various technical features in the foregoing embodiments are not described. However, as long as there is no contradiction in the combinations of these technical features, they should be considered to fall within the scope of this description.

The foregoing embodiments only express several implementation modes of the present disclosure, and the descriptions thereof are relatively specific and detailed, but they should not be understood as a limitation on the scope of the patent application. It should be noted that for a person of ordinary skill in the art, without departing from the concept of the present disclosure, several modifications and improvements can be made, and these all fall within the scope of protection of the present disclosure. Therefore, the scope of protection of this patent application shall be subject to the appended claims.

What is claimed is:

1. A method for manufacturing an oxide layer, comprising:
reacting a nitrogen-oxide-containing gas with hydrogen at a first temperature to form a first oxide layer, a volume concentration of the hydrogen in a first reaction gas being a first concentration; and
reacting oxygen with hydrogen at a second temperature, to form a second oxide layer on a surface of the first oxide layer, a volume concentration of the hydrogen in a second reaction gas being a second concentration;
wherein the first temperature is lower than the second temperature, and the first concentration is higher than the second concentration.

2. The method according to claim 1, wherein the first oxide layer and the second oxide layer are manufactured by using an In-Situ Steam Generation (ISSG) process.

3. The method according to claim 1, wherein the first temperature is 600° C. to 800° C.; and the second temperature is 800° C. to 1050° C.

4. The method according to claim 1, wherein the first temperature is 650° C. to 750° C., or 700° C. to 730° C.

5. The method according to claim 1, wherein the first temperature is 600° C., 650° C., 700° C., 720° C., 725° C., 750° C., or 800° C.

6. The method according to claim 1, wherein the second temperature is 900° C. to 1000° C., 950° C. to 980° C. or 970° C. or 975° C.

7. The method according to claim 1, wherein the first concentration is 5% to 33%; and the second concentration is less than 5%.

8. The method according to claim 1, wherein the first concentration is 10% to 25%, 20% to 23%, or 21% or 23%.

9. The method according to claim 1, wherein the second concentration is 1% to 3%.

10. The method according to claim 1, wherein the second concentration is 0.5%, 1%, 1.5%, 2.5%, 2%, 3%, 3.5%, 4.5%, or 4.5%.

11. The method according to claim 1, wherein the nitrogen-oxide-containing gas comprises at least one of nitrous oxide, nitric oxide, nitrogen dioxide, dinitrogen trioxide, dinitrogen tetroxide, and dinitrogen pentoxide.

12. The method according to claim 1, wherein a thickness of the first oxide layer accounts for 20%-50% of a thickness of the oxide layer.

13. An oxide layer manufactured by using the method according to claim 1.

14. A method for manufacturing a semiconductor structure comprising the method for manufacturing the oxide layer according to claim 1, further comprising:
providing a substrate;
forming an inter-gate dielectric layer on a surface of the substrate, wherein the inter-gate dielectric layer comprises the oxide layer;
forming a gate conductive layer on a surface of the inter-gate dielectric layer distal from the substrate;
patterning the inter-gate dielectric layer and the gate conductive layer to form a gate structure; and
forming a side wall on a sidewall of the gate structure.

15. The method according to claim 14, wherein the forming an inter-gate dielectric layer on a surface of the substrate further comprises:
forming a nitride layer on the surface of the oxide layer distal from the substrate, the nitride layer and the oxide layer together constituting the inter-gate dielectric layer.

16. The method according to claim 14, wherein the nitride layer comprises at least one of a plasma nitriding layer and a silicon oxynitride layer.

17. The method according to claim 14, wherein a shallow trench isolation structure is formed in the substrate, and the shallow trench isolation structure isolates a plurality of active regions in the substrate; and the inter-gate dielectric layer is formed on surfaces of the plurality of active regions.

18. A semiconductor structure manufactured by using the method according to claim 14.

19. A method for manufacturing a semiconductor structure comprising the method for manufacturing the oxide layer according to claim 2, further comprising:
providing a substrate;
forming an inter-gate dielectric layer on a surface of the substrate, wherein the inter-gate dielectric layer comprises the oxide layer;
forming a gate conductive layer on a surface of the inter-gate dielectric layer distal from the substrate;
patterning the inter-gate dielectric layer and the gate conductive layer to form a gate structure; and
forming a side wall on a sidewall of the gate structure.

20. A method for manufacturing a semiconductor structure comprising the method for manufacturing the oxide layer according to claim 3, further comprising:
providing a substrate;
forming an inter-gate dielectric layer on a surface of the substrate, wherein the inter-gate dielectric layer comprises the oxide layer;
forming a gate conductive layer on a surface of the inter-gate dielectric layer distal from the substrate;
patterning the inter-gate dielectric layer and the gate conductive layer to form a gate structure; and
forming a side wall on a sidewall of the gate structure.
